(19) United States
(12) Patent Application Publication
(10) Pub. No.: US 2006/0049888 A1
(43) Pub. Date: Mar. 9, 2006

(54) Voltage controlled oscillator

(75) Inventors: Ja Seung Gou, Gyeonggi-do (KR); Young Chul Sohn, Seoul (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 11/004,834

(22) Filed: Dec. 7, 2004

(30) Foreign Application Priority Data
Sep. 8, 2004 (KR) 10-2004-0071648

(51) Int. Cl. H03L 7/099

(52) U.S. Cl. 331/185

(57) ABSTRACT

A voltage controlled oscillator generates a signal having a predetermined cycle corresponding to change of an input power at a self-refresh mode of a DRAM. At the self-refresh mode for performing a refresh operation at every predetermined cycle of the DRAM, a start-up circuit unit provides a constant bias current to an oscillator unit regardless of change of the input power, thereby making the stable operation of the DRAM possible.

### BACKGROUND ART

1. Field of the Invention

The present invention generally relates to a voltage controlled oscillator, and more specifically, to a technology of generating a signal having a predetermined cycle corresponding to change of an input voltage in a voltage controlled oscillator used at a self-refresh mode of a DRAM.

2. Description of the Prior Art

Generally, in a DRAM, if a predetermined time passes after data are stored, the stored data are destroyed. As a result, the stored data can be preserved by activating a bit line sense amplifier BLSA and self-refreshing the stored data at every predetermined cycle.

FIG. 1 is a circuit diagram illustrating a conventional voltage controlled oscillator.

The conventional voltage controlled oscillator comprises a biasing circuit unit 10 and an oscillator unit 20.

The biasing circuit unit 10, which comprises a PMOS transistor P1, a NMOS transistor N1, resistors R1˜R5 and fuses F1˜F3, generates bias voltages BIAS1 and BIAS2.

The PMOS transistor P1, connected between a power voltage terminal and the resistor R1, has a diode structure where its gate is connected to its drain. The resistors R1˜R5 are connected serially between the PMOS transistor P1 and the NMOS transistor N1. The NMOS transistor N1, connected between the resistor R5 and a ground voltage terminal, has a diode structure where its gate is connected to its drain. The fuses F1˜F3 are connected in parallel to resistors R2˜R4, respectively.

The oscillator unit 20 comprises a first bias unit 21, a second bias unit 22 and an inverter unit 23.

The first bias unit 21 comprises a plurality of PMOS transistors P2˜P6 for supplying a power voltage to the inverter unit 23 depending on the bias voltage BIAS1 applied from the biasing circuit unit 10. The second bias unit 22 comprises a plurality of NMOS transistors N5˜N9 for supplying a ground voltage to the inverter unit 23 depending on the bias voltage BIAS2 applied from the biasing circuit unit 10.

The inverter unit 23 is comprised of an inverter chain including the odd number of inverters (PMOS transistor P7, NMOS transistor N7˜PMOS transistor P11, NMOS transistor N11). An output signal from the inverter (PMOS transistor P11, NMOS transistor N11) positioned at the final end is feedback inputted to an input terminal of the inverter (PMOS transistor P7, NMOS transistor N11) positioned at the initial end.

In the above-described conventional voltage controlled oscillator, since the PMOS transistors P2˜P6 and the NMOS transistors N2˜N6 of the oscillator unit 20 serve as load of the inverter unit 23, its operation point is determined depending on levels of the bias voltages BIAS1 and BIAS2 applied from the bias circuit unit 10.

The biasing level of the PMOS transistor P2 is determined by a drain voltage of the PMOS transistor P1 connected with the diode type. The biasing level of the NMOS transistor N2 is determined by a drain voltage of the NMOS transistor N1 connected with the diode type.

Current flowing in the PMOS transistors P2˜P6 and the NMOS transistors N2˜N6 is changed by regulating ratios of the resistors R1˜R5 corresponding to the selective connection state of the fuses F1˜F3. As a result, the cycle of the oscillator can be trimmed by setting the levels of the bias voltages BIAS1 and BIAS2 so that the PMOS transistors P2˜P6 and the NMOS transistors N2˜N6 may be operated in a linear region.

The DRAM performs a repeated self-refresh operation depending on the operation cycle of the above-described voltage controlled oscillator at a self-refresh mode. As a result, the oscillator unit 20 of the voltage controlled oscillator generates a signal having a predetermined cycle to determine the cycle of the self-refresh operation.

In other words, the oscillator unit 20 determined the cycle of the self-refresh operation by regulating current required in the operation of the inverter unit 23 with the first bias unit 21 and the second bias unit 22. The biasing circuit unit 10 determines the level of the bias voltage supplied to the oscillator 20 with the resistors R1˜R5.

However, in the conventional voltage controlled oscillator, if the level of the input power is changed by power noise generated in the internal operation of the DRAM, the level of the bias voltage supplied from the biasing circuit unit 10 is changed, so that a cycle of an output signal from the oscillator unit 20 is changed.

In case of DDRII, when a power voltage is operated at a low power 1.6V, a voltage margin obtained by subtracting operation voltages of the PMOS transistor P7 and the NMOS transistor N7 becomes lower than threshold voltages of the PMOS transistor P2 and the NMOS transistor N2. As a result, the PMOS transistor P2 and the NMOS transistor N2 are operated in a cut-off region.

The amount of the bias current flowing in the PMOS transistor P2 and the NMOS transistor N2 becomes different from a value of the linear region, so that the cycle of the output signal from the oscillator unit 20 is changed.

### SUMMARY OF THE INVENTION

Accordingly, it is an object of the present invention to generate a signal having a predetermined cycle by providing a constant current to an oscillator corresponding to change of an input power.

In an embodiment, a voltage controlled oscillator comprises a biasing circuit unit, a start-up circuit unit and an oscillator unit. The biasing circuit unit generates a constant bias voltage depending on a constant current value generated by a current mirror. The start-up circuit unit controls a level of the bias voltage corresponding to a voltage level of an input voltage in a self-refresh mode. The oscillator unit generates successive pulse signals each having a constant oscillating cycle depending on the bias voltage.

### BRIEF DESCRIPTION OF THE DRAWINGS

Other aspects and advantages of the present invention will become apparent upon reading the following detailed description and upon reference to the drawings in which:

FIG. 1 is a circuit diagram illustrating a conventional voltage controlled oscillator; and

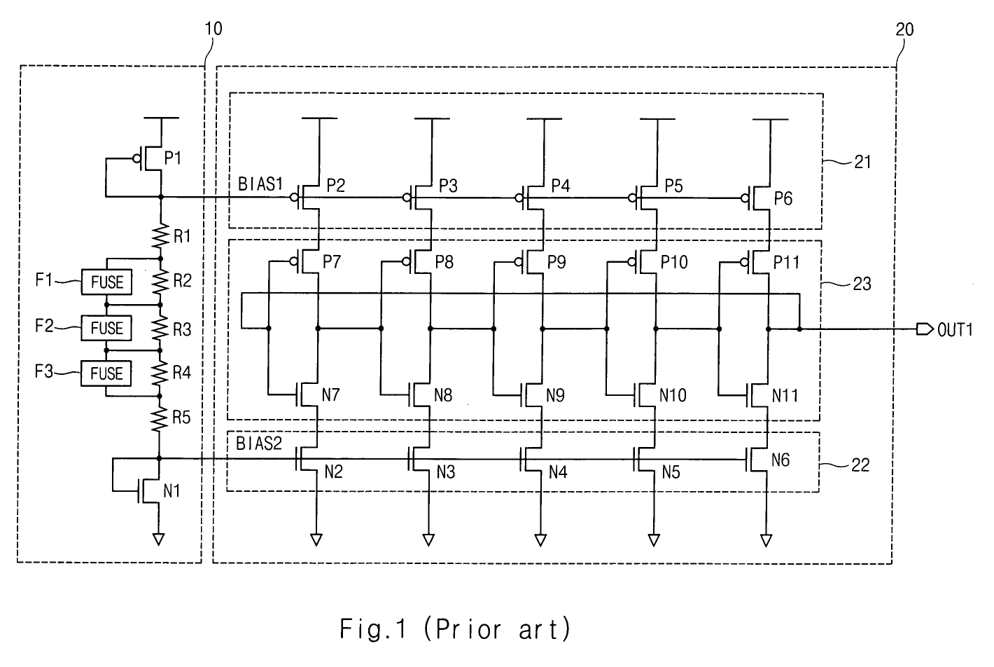

FIG. 2 is a circuit diagram illustrating a voltage controlled oscillator according to an embodiment of the present invention.

### DETAILED DESCRIPTION OF THE PREFERRED EMBODIMENTS

The present invention will be described in detail with reference to the accompanying drawings.

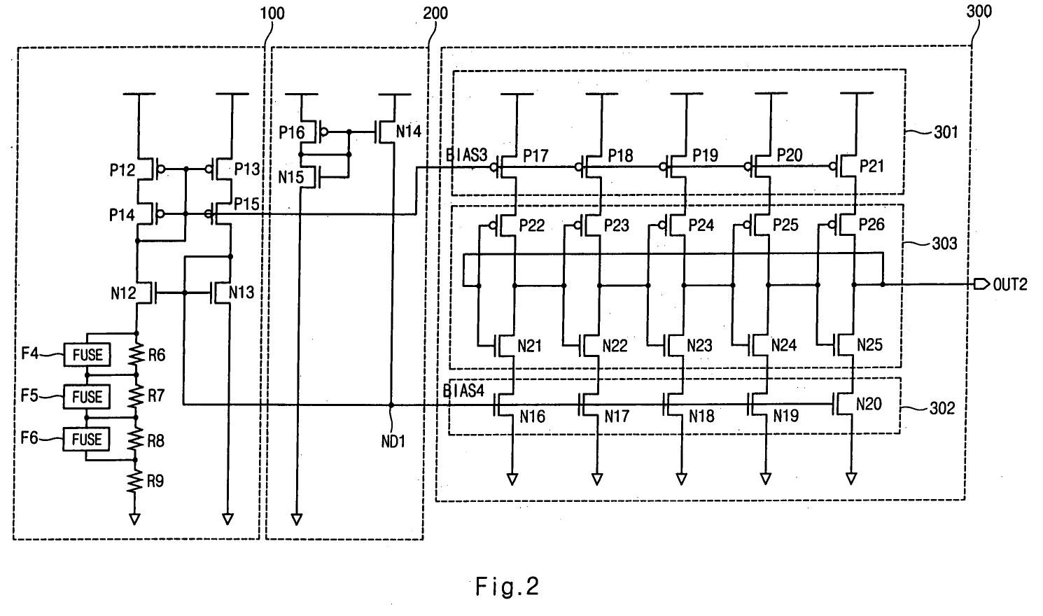

FIG. 2 is a circuit diagram illustrating a voltage controlled oscillator according to an embodiment of the present invention.

In an embodiment, the voltage controlled oscillator comprises a biasing circuit unit 100, a start-up circuit unit 200 and an oscillator unit 300.

Here, the biasing circuit unit 100 comprises PMOS transistors P12˜P15, NMOS transistors N12˜N13, resistors R6˜R9 and fuses F4˜F6.

A current mirror, which comprises the PMOS transistors P12˜P15 and the NMOS transistors N12˜N13, serves as a constant voltage source to generate bias voltages BIAS3 and BIAS4. The PMOS transistors P12˜P15 that are formed of two stages of paired transistors bias a gate voltage level at a drain voltage level of the PMOS transistor P14.

The PMOS transistors P12˜P15 have each gate connected in common which is connected to a drain of the PMOS transistor P14. The NMOS transistors N12˜N13 have each gate connected in common which is connected to a drain of the NMOS transistor N13.

The resistor R6˜R9, connected serially between the NMOS transistor N12 and a ground voltage terminal, regulate drain/source voltages (Vds) of the NMOS transistor N12. The fuses F4˜F6, connected in parallel to both ends of the resistors R6˜R8. As a result, a resistance value between the NMOS transistor N12 and the ground voltage terminal is regulated depending on selective connection states of the fuses F4˜F6.

The start-up circuit unit 200 comprises a PMOS transistor P16 and NMOS transistors N14 and N15 whose gates are connected in common.

The PMOS transistor P16, connected between a power voltage terminal and the NMOS transistor N15, has a diode structure where its gate is connected in common to its drain. The NMOS transistor N14, connected between the power voltage terminal and a node ND1, has a gate connected in common to the PMOS transistor P16 and the NMOS transistor N15.

Here, a source of the NMOS transistor N14 is connected to the gate of the NMOS transistors N12 and N13 to maintain a predetermined level of a voltage. The NMOS transistor N15, connected between the PMOS transistor P16 and the ground voltage terminal, has a diode structure where its gate is connected in common to its drain.

The oscillator unit 300 comprises a third bias unit 301, a fourth bias unit 302 and an inverter unit 303.

The third bias unit 301 comprise a plurality of PMOS transistors P17˜P21 for supplying a power voltage to the inverter unit 303 depending on the bias voltage BIAS3 applied from the biasing circuit unit 100. The fourth bias unit 302 comprises a plurality of NMOS transistors N16˜N20 for supplying a ground voltage to the inverter unit 303 depending on the bias voltage BIAS4 applied from the biasing circuit unit 100.

The inverter unit 303 is comprised of an inverter chain including the odd number of inverters (PMOS transistors P22, NMOS transistors N21˜PMOS transistor P26, NMOS transistor N25). An output signal from the inverter (PMOS transistor P26, NMOS transistor N25) positioned at the final end is feedback inputted to an input terminal of the inverter (PMOS transistor P22, NMOS transistor N21) positioned at the initial end, thereby outputting successive pulses. Also, in the inverter unit 303, an output signal from the previous inverter is inputted to the next inverter.

Hereinafter, the operation of the voltage controlled oscillator according to an embodiment of the present invention is described.

The PMOS transistors P12˜P15 of the biasing circuit unit 100 has a current mirror structure, and perform a gate biasing operation with a drain voltage of the PMOS transistor P14. The NMOS transistors N12 and N13 perform a gate biasing operation with a drain voltage of the NMOS transistor N13.

The oscillator unit 300 which comprises the odd number of inverters generates successive pulse signals by inverting an input signal. The degree of increase and decrease in a voltage level of the biasing circuit unit 100 is transmitted as input of the oscillator unit 300 to regulate the self-refresh operation of the oscillator unit 300.

As a result, the levels of the bias voltages BIAS3 and BIAS4 are set so that the biasing circuit unit 100 may be in a saturation region to change of an input power. That is, an operation current of the bias voltage BIAS3 applied to the PMOS transistor P17 is identical with current Ids flowing in the PMOS transistor P15. An operation current of the bias voltage BIAS4 applied to the NMOS transistor N16 is identical with current Ids flowing in the NMOS transistor N13.

Since the inverter comprised of the PMOS transistor 22 and the NMOS transistor 21 is operated depending on the same current Ids value to the change of the input power, the cycle of the oscillator unit 300 becomes fixed.

The PMOS transistor P17 and the NMOS transistor N16 are operated not in the linear region but in the saturation region. Thus, the voltage controlled oscillator according to an embodiment of the present invention is operated at a voltage level of about 1.4V which is more than addition of threshold voltages of the PMOS transistors P17 and the NMOS transistor N16. As a result, the voltage controlled oscillator can generate a pulse signal having a predetermined cycle by providing a constant current to the oscillator unit 300 even in a low power voltage region.

Here, the start-up circuit unit 200 controls the levels of the bias voltages BIAS3 and BIAS4 in the low power voltage region.

That is, when the bias voltage BIAS4 is around 0V, a gate voltage level of the NMOS transistor N14 becomes lower to turn on the PMOS transistor P16. Then, the gate voltage level of the NMOS transistor N14 becomes higher, so that the level of the bias voltage BIAS4 becomes also higher. In other words, if the gate voltage level of the NMOS transistor N14 becomes higher, the NMOS transistor N16 is turned on to increase the level of the bias voltage BIAS4.

When the level of the input power is high, the NMOS transistor N15 is turned on. Then, the gate voltage level of the NMOS transistor N14 becomes lower to turn off the NMOS transistor N14. As a result, the NMOS transistor N14 is configured to increase the level of the bias voltage BIAS4 in the low power voltage region and to be kept at a turn-off state in a high power voltage region.

Thereafter, the oscillator unit 300 generates a predetermined pulse signal by providing a constant bias current depending on the values of the bias voltages BIAS3 and BIAS4 applied from the biasing circuit unit 100 to the inverter unit 303.

As discussed earlier, a voltage controlled oscillator according to an embodiment of the present invention generates a self-refresh signal having a predetermined cycle regardless of change of an input power in the voltage controlled oscillator used in a self-refresh operation of a DRAM.

While the invention is susceptible to various modifications and alternative forms, specific embodiments have been shown by way of example in the drawings and described in detail herein. However, it should be understood that the invention is not limited to the particular forms disclosed. Rather, the invention covers all modifications, equivalents, and alternatives falling within the spirit and scope of the invention as defined in the appended claims.

What is claimed is:

1. A voltage controlled oscillator comprising:
a biasing circuit unit for generating a constant bias voltage depending on a constant current value generated by a current mirror;
a start-up circuit unit for controlling a level of the bias voltage corresponding to a voltage level of an input voltage in a self-refresh mode; and
an oscillator unit for generating successive pulse signals each having a constant oscillating cycle depending on the bias voltage.

2. The voltage controlled oscillator according to claim 1, wherein the biasing circuit unit comprises:
a current mirror, which comprises a pair of PMOS transistors and a pair of NMOS transistors, for generating the bias voltage;
a resistor unit, which is connected serially between the current mirror and a ground voltage terminal, for controlling a current value of the current mirror; and
a fuse unit, which is connected in parallel to the resistor unit, for regulating a resistance value of the resistor unit.

3. The voltage controlled oscillator according to claim 2, wherein the current mirror comprises:
a plurality of paired PMOS transistors, which are connected between a power voltage terminal and the pair of NMOS transistors, having a gate connected in common; and
a pair of NMOS transistors, which are connected between the plurality of paired PMOS transistors and the resistor unit, for outputting the bias voltage through a common gate.

4. The voltage controlled oscillator according to claim 1, wherein the start-up circuit unit comprises:
a first driving means which is turned on at an initial operation in a low power voltage region for rising the level of the bias voltage for a predetermined time and then is turned off after the predetermined time;
a second driving means for providing a driving voltage to the first driving means in the low power voltage region; and
a third driving means which is turned on after the predetermined time to turn off the first driving means.

5. The voltage controlled oscillator according to claim 4, wherein the first driving means comprises a first NMOS transistor, connected between a power voltage terminal and a terminal for receiving the bias voltage, having a gate connected in common to the second driving means and the third driving means.

6. The voltage controlled oscillator according to claim 4, wherein the second driving means comprises a PMOS transistor, connected between a power voltage terminal and the third driving means, having a gate connected in common to the first driving means and the third driving means.

7. The voltage controlled oscillator according to claim 4, wherein the third driving means comprises a second NMOS transistor, connected between the second driving means and a ground voltage terminal, having a gate connected in common to the first driving means and the second driving means and a drain connected in common to the second driving means.
